(19) United States
(12) Patent Application Publication
(10) Pub. No.: US 2012/0319283 A1
(43) Pub. Date: Dec. 20, 2012

(54) SEMICONDUCTOR DEVICE HAVING EXTERNAL ELECTRODES EXPOSED FROM ENCAPSULATION MATERIAL

(75) Inventor: Toru KANNO, Niiza-shi (JP)

(73) Assignee: Sanken Electric Co., Ltd., Niiza-shi (JP)

(21) Appl. No.: 13/489,001

(22) Filed: Jun. 5, 2012

(30) Foreign Application Priority Data
Jun. 20, 2011 (JP) 2011-136365

(51) Int. Cl. H01L 29/861

(52) U.S. Cl. 257/771; 257/E29.327

(57) ABSTRACT

A semiconductor device includes a semiconductor element including an anode electrode and a cathode electrode, an encapsulating material which covers the semiconductor element, a first external electrode which is electrically connected to the cathode electrode and is at least partially exposed outside of the encapsulating material, a second external electrode which is electrically connected to the anode electrode and is at least partially exposed outside of the encapsulating material, and a sacrificial metallic body which is arranged outside of the encapsulating material so as to be in direct contact with the first external electrode or to be electrically connected to the first external electrode through saltwater, and contains metal having larger ionization tendency than any metal contained in the first external electrode.

### CROSS REFERENCE TO RELATED APPLICATIONS AND INCORPORATION BY REFERENCE

This application is based upon and claims the benefit of priority from prior Japanese Patent Application P2011-136365 filed on Jun. 20, 2011; the entire contents of which are incorporated by reference herein.

### BACKGROUND OF THE INVENTION

1. Field of the Invention

The present invention relates to a semiconductor device having external electrodes which are connected to a semiconductor element covered by an encapsulating material.

2. Description of the Related Art

An effective way to protect a semiconductor element such as a diode for an alternator is, for example, to cover the semiconductor element with an encapsulating material such as resin. At this time, external electrodes such as a lead electrode and a base electrode which are respectively connected to a negative electrode and a positive electrode of the semiconductor element covered by the encapsulating material are exposed outside of the encapsulating material.

As such a semiconductor device, a semiconductor device has been proposed which has a structure where a lead electrode is made partially thick. Because of a large diameter of the lead electrode, tolerance to salt damage is improved even if the lead electrode is corroded due to salt damage.

To enhance reliability of a semiconductor device, there are needs for further improvement of tolerance of external electrodes to corrosion due to salt damage.

### SUMMARY OF THE INVENTION

An aspect of the present invention is a semiconductor device. The semiconductor device includes a semiconductor element including an anode electrode and a cathode electrode; an encapsulating material which covers the semiconductor element; a first external electrode which is electrically connected to the cathode electrode and is at least partially exposed outside of the encapsulating material; a second external electrode which is electrically connected to the anode electrode and is at least partially exposed outside of the encapsulating material; and a sacrificial metallic body which is arranged outside of the encapsulating material so as to be in direct contact with the first external electrode or to be electrically connected to the first external electrode through salt water, and contains metal having larger ionization tendency than any metal contained in the first external electrode.

### BRIEF DESCRIPTION OF THE DRAWINGS

FIG. 1 is a schematic cross-sectional view showing a structure of a semiconductor device according to an embodiment of the present invention;

FIG. 2 is a schematic external view showing the structure of the semiconductor device according to the embodiment of the present invention;

FIG. 3 is a schematic view showing an example of a voltage test in salt water conducted on a semiconductor device according to a comparative example;

FIG. 4 is a schematic cross-sectional view showing a structure of a semiconductor device according to a modified example of the embodiment;

FIG. 5 is a schematic external view showing a structure of a semiconductor device according to another modified example of the embodiment;

FIGS. 6A and 6B are schematic views showing a structure of a semiconductor device according to another modified example of the embodiment;

FIG. 7 is a schematic external view showing a structure of a semiconductor device according to another modified example of the embodiment;

FIG. 8 is a schematic external view showing a structure of a semiconductor device according to another modified example of the embodiment;

FIG. 9 is a schematic external view showing a structure of a semiconductor device according to another modified example of the embodiment; and

FIG. 10 is a schematic cross-sectional view showing a structure of a semiconductor device according to another modified example of the embodiment.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

In the following descriptions, numerous specific details are set forth such as specific signal values, etc., to provide a thorough understanding of the present invention. However, it will be obvious to those skilled in the art that the present invention may be practiced without such specific details.

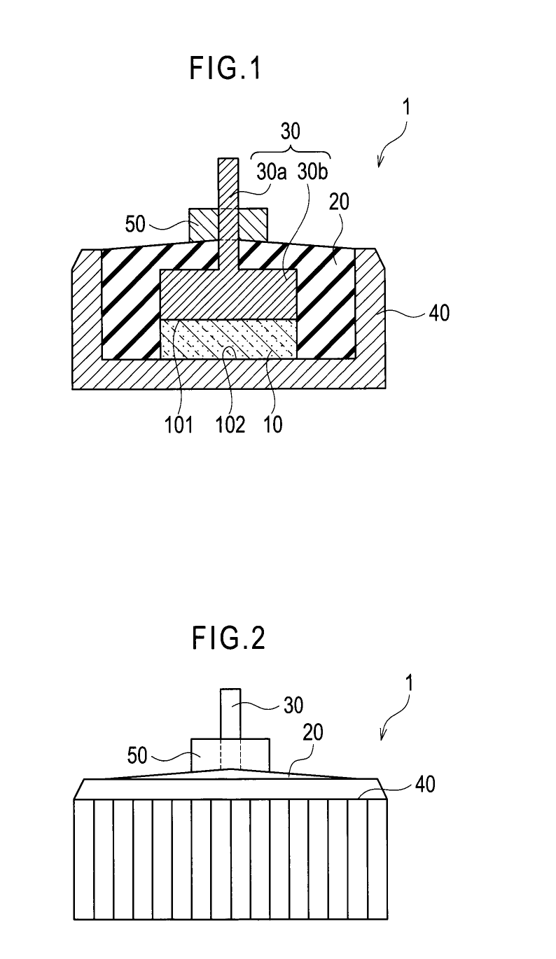

As illustrated in FIG. 1, a semiconductor device 1 according to an embodiment of the present invention includes a semiconductor element 10 having a cathode electrode 101 and an anode electrode 102, an encapsulating material 20 which covers the semiconductor element 10, a first external electrode 30 which is electrically connected to the cathode electrode 101 and is at least partially exposed outside of the encapsulating material 20, a second external electrode 40 which is electrically connected to the anode electrode 102 and is at least partially exposed outside of the encapsulating material 20, and a sacrificial metallic body 50 which is arranged outside of the encapsulating material 20 to be in contact with the first external electrode 30. The sacrificial metallic body 50 contains metal having higher ionization tendency than any metal contained in the first external electrode 30. The cathode electrode 101 is formed on a surface of the semiconductor element 10 which is in contact with the first external electrode 30, and the anode electrode 102 is formed on a surface of the semiconductor element 10 which is in contact with the second external electrode 40.

In an embodiment shown in FIG. 1, the second external electrode 40 has a cap shape having an outer diameter ranging from approximately 5 mm to 15 mm. The inner side of the second external electrode 40 in which the semiconductor element 10 is positioned is filled with the encapsulating material 20 such as resin. The semiconductor element 10 is protected by being covered with the encapsulating material 20. Examples of the encapsulating material 20 include epoxy resin and a rubber film.

The first external electrode 30 shown in FIG. 1 is a lead electrode constituted of a connection section 30b which is connected to the semiconductor element 10, and a drawn-out section 30a which is exposed outside of the encapsulating material 20. As illustrated in FIG. 1, the drawn-out section 30a is partially buried in the encapsulating material 20. Covering the connection between the semiconductor element 10 and the first external electrode 30 with the encapsulating material 20 in the above-mentioned way is preferred from the aspect of protection of the semiconductor element 10. The drawn-out section 30a of the first external electrode 30 has a pin shape with a diameter ranging from 0.9 mm to 2.0 mm and a length ranging from 5.0 mm to 30.0 mm.

The semiconductor element 10 is, for example, a diode for an alternator. In a case where the semiconductor element 10 is a diode, the first external electrode 30 is connected to the cathode electrode 101 of the semiconductor element 10, and the second external electrode 40 is connected to the anode electrode 102 of the semiconductor element 10. The first external electrode 30 and the second external electrode 40 are connected to the semiconductor element 10 using a conductive adhesive such as solder.

FIG. 2 shows an example of an external view of the semiconductor device 1. The semiconductor device 1 shown in FIG. 2 is a press-fit element, and the second external electrode 40 serves as a support for the semiconductor element 10 and works as a plug to be inserted in a mounting hole in a substrate or the like. For the second external electrode 40, metal having high electrical conductivity is used, but it is preferred that a material which also has high thermal conductivity be used in order to allow the second external electrode 40 to work as a heat sink as well. For example, copper (Cu) is used for the second external electrode 40. However, considering the manufacturing process of the semiconductor device 1, it is preferred to plate a copper material with nickel (Ni) in order to protect the copper material.

The structure of Ni -plated Cu material can also be adopted for the pin-shaped first external electrode 30.

The sacrificial metallic body 50 shown in FIGS. 1 and 2 is an example where cylindrically-shaped aluminum (Al) having an inner diameter of 2.4 mm, an outer diameter of 2.7 mm, and a length of 5.0 mm is used.

It is preferred that the sacrificial metallic body 50 have a circular or rectangular sectional shape so as to surround the drawn-out section 30a, and a part of the sacrificial metallic body 50 may be buried in the encapsulating material 20. Also, the sacrificial metallic body 50 has an outer diameter ranging from 0.9 mm to 15 mm (in other words, ranging from the diameter of the first external electrode 30 to the outer diameter of the second external electrode 40), and an inner diameter thereof is similar to the outer diameter considering a case of plating. The length of the exposed portion ranges from 0.5 mm to 30.0 mm (in other words, from the minimum length to the length which covers the entire first external electrode 30).

A method for manufacturing the semiconductor device 1 will be explained below. First of all, the first external electrode 30 is firmly fixed on the cathode electrode 101 of the semiconductor element 10 through a conductive adhesive, and the anode electrode 102 of the semiconductor element 10 is firmly fixed to the inner side of the second external electrode 40 through a conductive adhesive. Next, the encapsulating material 20 is filled in the inner side of the second external electrode 40 in order to seal the semiconductor element 10, and thereafter, the sacrificial metallic body 50 is placed so as to contact the first external electrode 30, thus completing the semiconductor device 1.

The sacrificial metallic body 50 may be plated before the first external electrode 30 is firmly fixed on the semiconductor element 10 or before the encapsulating material 20 is filled in the second external electrode 40. A method for mounting the sacrificial metallic body 50 may be selected from well-known processes including bonding using an adhesive, welding, compression bonding, plating, paint application, and vapor deposition.

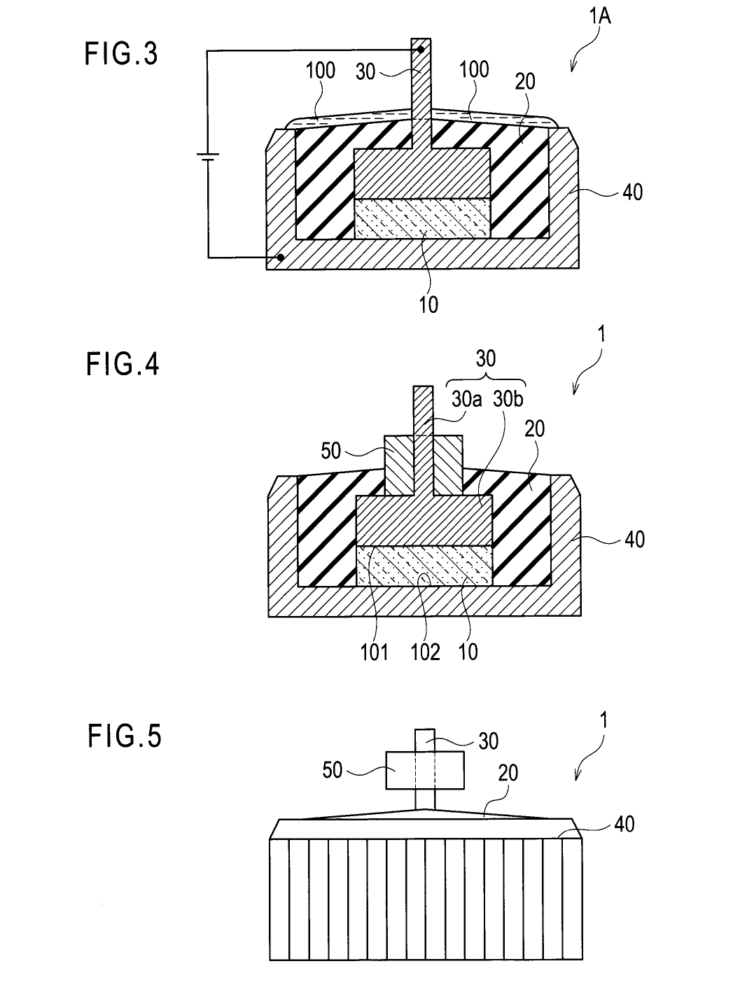

Here, salt damage will be explained taking a semiconductor device 1A of a comparative example shown in FIG. 3 as an example. Similarly to the semiconductor device 1 shown in FIG. 1, the semiconductor device 1A has a structure where a first external electrode 30 and a second external electrode 40 are mounted on a semiconductor element 10, and the semiconductor element 10 is covered with an encapsulating material 20 which is filled in the inner side of the second external electrode 40. However, a sacrificial metallic body 50 is not provided in the semiconductor device 1A.

Salt damage happens as the first external electrode 30 and the second external electrode 40 are electrically connected to each other due to salt water which has gathered on the upper surface of the encapsulating material 20. FIG. 3 shows an example where a voltage test in salt water was conducted on the semiconductor device 1A as a salt damage test.

In the voltage test in salt water, salt water is sprayed on the semiconductor device 1A, and at the same time, a reverse voltage ranging from several V to several tens of V is applied between the second external electrode 40 (anode electrode) and the first external electrode 30 (cathode electrode) of the semiconductor device 1A.

Once the voltage test in salt water is conducted, salt water 100 sprayed onto the semiconductor device 1A gathers on the surface of the encapsulating material 20 as illustrated in FIG. 3. When the salt water 100 which has gathered comes in contact with the first external electrode 30 serving as a cathode electrode and the second external electrode 40 serving as an anode electrode, electrolysis of the saltwater 100 begins due to the reverse voltage applied to the semiconductor element 10. Because of the electrolysis, acidic hydrogen chloride (HCl) is generated around the first external electrode 30 to which positive electric potential is applied. Meanwhile, alkaline sodium hydroxide (NaOH) is generated around the second external electrode 40 to which negative electric potential is applied.

The encapsulating material 20 has high corrosion resistance to an acidic fluid, and the second external electrode 40 has high corrosion resistance to an alkaline fluid. However, due to HCl generated around the first external electrode 30, corrosion occurs in the first external electrode 30.

On the contrary, in the semiconductor device 1 shown in FIG. 1, the sacrificial metallic body 50 which contains metal having larger ionization tendency than metal contained in the first external electrode 30 is arranged so as to be in electrical contact with the first external electrode 30. Since the sacrificial metallic body 50, which is made of base metal compared to the meal contained in the first external electrode 30, is in electric contact with the first external electrode 30, corrosion of the sacrificial metallic body 50 begins before the first external electrode 30 is corroded. While corrosion of the sacrificial metallic body 50 is happening, corrosion of the first external electrode 30 does not occur because of the sacrificial corrosion. As a result, the lifetime of the semiconductor device 1 is improved with regard to salt damage.

As a result of the voltage test in salt water carried out by the inventors under the aforementioned conditions, the semiconductor device 1A of the comparative example had corrosion in the first external electrode 30 (cathode electrode) within less than 100 hours. Meanwhile, in the semiconductor device 1 shown in FIG. 1, no corrosion was observed in the first external electrode 30 even after a lapse of over 200 hours.

To take countermeasures to salt damage in order to suppress corrosion of the first external electrode 30 by utilizing sacrificial corrosion of the sacrificial metallic body 50, the first external electrode 30 connected to the cathode electrode 10 of the semiconductor element 10 and the sacrificial metallic body 50 need to be in electrical contact with each other. Therefore, in the semiconductor device 1 illustrated in FIG. 1, the sacrificial metallic body 50 and the first external electrode 30 are brought into contact with each other at the root portion of the first external electrode 30 which is in contact with the encapsulating material 20.

For example, in a case where the first external electrode 30 is constituted by plating Ni on a Cu material, Ni has larger ionization tendency than Cu. Therefore, metal having larger ionization tendency than Ni is used as the sacrificial metallic body 50. Specifically, metal which contains aluminum (Al), iron (Fe), zinc (Zn), magnesium (Mg) and so on may be used for the sacrificial metallic body 50. Among these metals, Al is preferred as it is inexpensive and easily processed. An alloy of Al and Mg is more preferred. For instance, an amount of Mg added may range from 0.5% to 5.6%. By using an alloy of Al and Mg as the sacrificial metallic body 50, a corrosion prevention action of the sacrificial metallic body 50 can be maintained compared to the use of Al for the sacrificial metallic body 50, thus improving the lifetime. The result of the voltage test in salt water explained above was acquired from the use of an alloy of Al and Mg for the sacrificial metallic body 50.

In the semiconductor device 1 shown in FIG. 1, a sacrificial corrosion effect is produced as the sacrificial metallic body 50 arranged at the root portion of the first external electrode 30 comes in electrical contact with the first external electrode 30 and salt water which has gathered around the root portion of the first external electrode 30.

The tolerance of the semiconductor device 1 to salt damage can be improved by the sacrificial corrosion effect by adopting not only the structure of the semiconductor device 1 shown in FIG. 1 but also any other structure thereof as long as salt water which is in contact with the first external electrode 30 and the second external electrode 40, and the sacrificial metallic body 50 which is base metal compared to the first external electrode 30 are in electrical contact with each other. In short, regardless of shapes and mounting positions of the sacrificial metallic body 50, as well as packages in which the semiconductor device 1 is mounted, the aforementioned sacrificial corrosion effect can be achieved.

For example, as illustrated in FIG. 4, the sacrificial metallic body 50 may be provided in such a way that the sacrificial metallic body 50 is partially buried in the encapsulating material 20. Alternatively, as shown in FIG. 5, the sacrificial metallic body 50 may be in contact with the first external electrode 30 at a position away from the encapsulating material 20 without covering the root portion of the first external electrode 30.

Further, even if the sacrificial metallic body 50 is not in direct contact with the first external electrode 30, the sacrificial corrosion effect can still be achieved as long as the sacrificial metallic body 50 and the first external electrode 30 are in electric contact with each other due to, for example, salt water which has entered in a gap between the sacrificial metallic body 50 and the first external electrode 30. In other words, the sacrificial metallic body 50 may be arranged outside of the encapsulating material 20 in such a way that the sacrificial metallic body 50 can be electrically connected to the first external electrode 30 through salt water.

Hence, when the first external electrode 30 has a shape which makes it difficult to bring the sacrificial metallic body 50 into contact with the root portion of the first external electrode 30, it is also effective to use the sacrificial metallic body 50 having a ring shape or to coat the first external electrode 30 with the sacrificial metallic body 50.

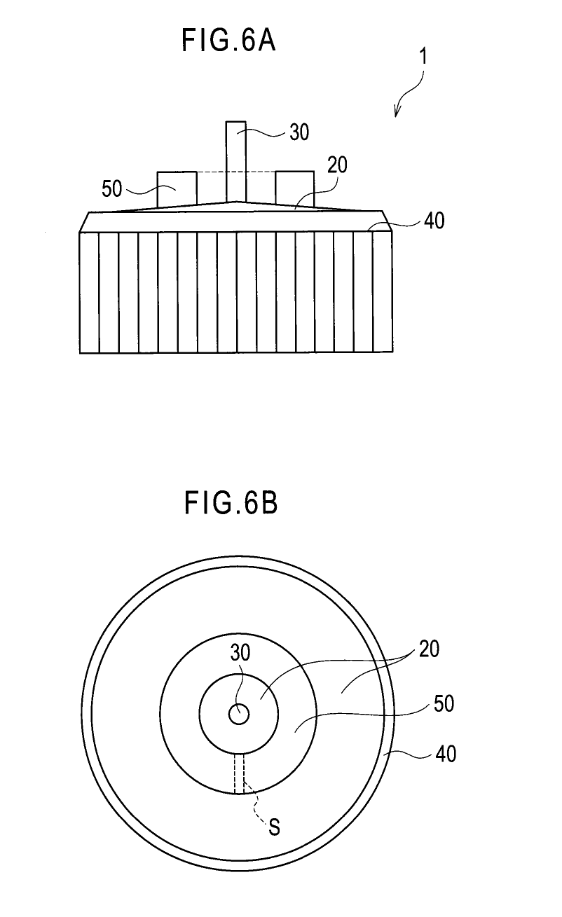

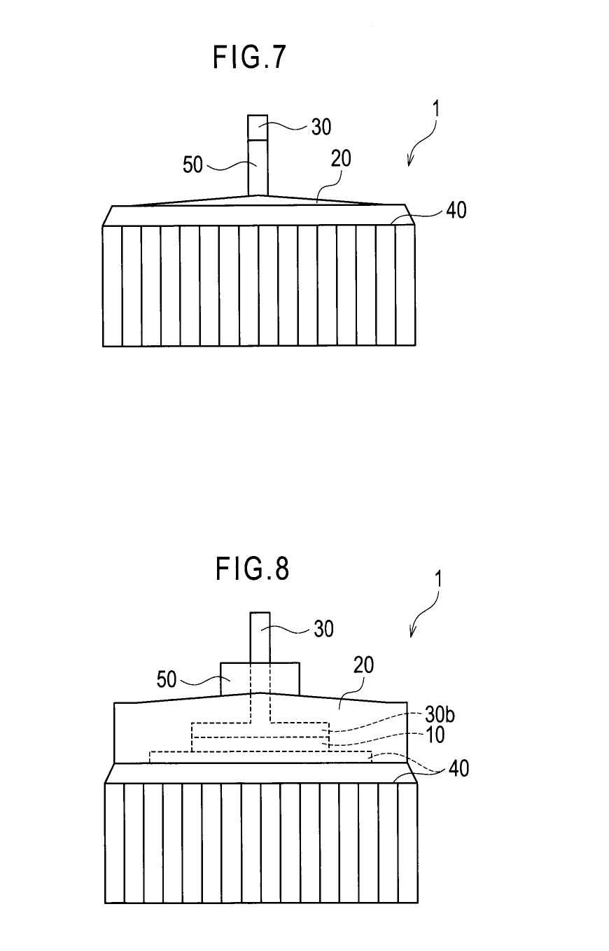

For example, like the semiconductor device 1 shown in FIGS. 6A and 6B, a ring-shaped sacrificial metallic body 50 may be arranged on the encapsulating material 20 so as to surround the root portion of the first external electrode 30. In FIG. 6A, the first external electrode 30 is shown through the sacrificial metallic body 50. Also, a slit S like the one shown in a dashed line in FIG. 6B may be provided in the sacrificial metallic body 50 in consideration of manufacturing processes. Also, like the semiconductor device 1 shown in FIG. 7, a sacrificial metallic body 50 may be coated on the first external electrode 30 using a plating process and so on.

Moreover, as shown in FIG. 8, in the semiconductor device 1 in which the encapsulating material 20 is formed by covering an upper part of a convex-shaped second external electrode 40, a sacrificial corrosion effect can be achieved by bringing the sacrificial metallic body 50 into electric contact with a first external electrode 30. In the semiconductor device 1 shown in FIG. 8, a semiconductor element 10 and the first external electrode 30 are placed on the convex-shaped portion of the second external electrode 40. In FIG. 8, the semiconductor element 10 and the first external electrode 30, as well as the convex-shaped portion of the second external electrode 40, which are in a region covered by the encapsulating material 20, are shown in a dashed line.

In the case of the semiconductor device 1 illustrated in FIG. 8, it goes without saying that the sacrificial metallic body 50 can also be arranged in the semiconductor device 1 in various forms like the modified examples illustrated in FIGS. 4 to 7 of the semiconductor device 1 shown in FIG. 1.

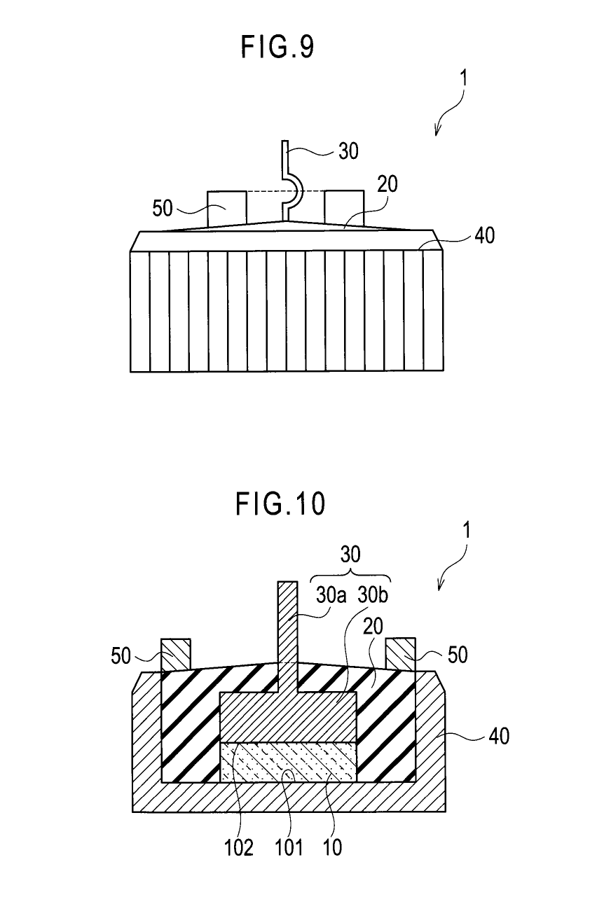

Further, with regard to a semiconductor device 1 in which the first external electrode 30 has a pin shape that includes a bend portion, the sacrificial metallic body 50 may be arranged, for example, as shown in FIG. 9. FIG. 9 represents an example in which the sacrificial metallic body 50 having a ring shape is arranged on an encapsulating material 20 so as to surround the root portion of the first external electrode 30. In FIG. 9, the first external electrode 30 is illustrated through the sacrificial metallic body 50. The sacrificial corrosion effect can also be achieved in the semiconductor device 1 depicted in FIG. 9.

Thus, reliability of the semiconductor device 1 can be enhanced in terms of salt damage while maintaining a function of a lead bend.

Yet further, in a semiconductor device having an opposite polarity to the semiconductor device 1 shown in FIG. 1, the sacrificial metallic body 50 may be arranged, for example, as illustrated in FIG. 10. FIG. 10 shows an example in which the first external electrode 30 is electrically connected to the anode electrode 102 of the semiconductor element 10, the second external electrode 40 is electrically connected to the cathode electrode 101 of the semiconductor element 10, and the sacrificial metallic body 50 is brought into contact with the second external electrode 40 at a connection between the second external electrode 40 and the encapsulating material 20. The sacrificial corrosion effect is also achieved in the semiconductor device 1 shown in FIG. 10.

As explained so far, with the semiconductor device 1 according to the embodiment of the pre sent invention, corrosion of the first external electrode 30 due to salt damage can be inhibited by bringing the sacrificial metallic body 50 having larger ionization tendency than the materials of the first external electrode 30 into electric contact with the first external electrode 30. As a result, reliability of the semiconductor device 1 on salt damage can be improved.

Various modifications will become possible for those skilled in the art after receiving the teachings of the present disclosure without departing from the scope thereof.

What is claimed is:

1. A semiconductor device, comprising:
a semiconductor element including an anode electrode and a cathode electrode;
an encapsulating material which covers the semiconductor element;
a first external electrode which is electrically connected to the cathode electrode and is at least partially exposed outside of the encapsulating material;
a second external electrode which is electrically connected to the anode electrode and is at least partially exposed outside of the encapsulating material; and
a sacrificial metallic body which is arranged outside of the encapsulating material so as to be in direct contact with the first external electrode or to be electrically connected to the first external electrode through salt water, and contains metal having larger ionization tendency than any metal contained in the first external electrode.

2. The semiconductor device according to claim 1, wherein the first external electrode includes a pin-shaped drawn-out section which is exposed outside of the encapsulating material, and the sacrificial metallic body is arranged so as to surround the drawn-out section.

3. The semiconductor device according to claim 1, wherein the sacrificial metallic body is arranged to be in contact with a connection between the first external electrode and the encapsulating material.

4. The semiconductor device according to claim 1, wherein the sacrificial metallic body is arranged so as to surround a connection between the first external electrode and the semiconductor element.

5. The semiconductor device according to claim 1, wherein the sacrificial metallic body is made of aluminum.

6. The semiconductor device according to claim 1, wherein the sacrificial metallic body is made of an alloy of aluminum and magnesium.
